(19) United States
(12) Patent Application Publication
(10) Pub. No.: US 2008/0043447 A1
(43) Pub. Date: Feb. 21, 2008

(54) Semiconductor package having laser-embedded terminals

(75) Inventors: Ronald Patrick Huemoeller, Chandler, AZ (US); Sukianto Rusli, Phoenix, AZ (US); David Jon Hiner, Chandler, AZ (US)

Correspondence Address: GUNNISON MCKAY & HODGSON, LLP;GARDEN WEST OFFICE PLAZA, SUITE 220, 1900 GARDEN ROAD, MONTEREY, CA, 93940, US

(73) Assignee: AMKOR TECHNOLOGY, INC.

(21) Appl. No.: 11/182,985

(22) Filed: Jul. 14, 2005

Related U.S. Application Data
(63) Continuation-in-part of application No. 10/603,878, filed on Jun. 24, 2003, now Pat. No. 7,028,400.
Application No. 10/603,878 is a continuation-in-part of application No. 10/138,225, filed on May 1, 2002, now Pat. No. 6,930,256.

(51) Int. Cl. H05K 7/00

(52) U.S. Cl. 361/748

(57) ABSTRACT

A semiconductor package having laser-embedded terminals provides a high-density and low cost internal/external mounting and interconnect structure for integrated circuits. A substrate for interconnecting one or more dies to external terminals of the semiconductor package is fabricated with terminal lands buried inside the dielectric. The terminal lands are exposed by laser-ablation and then terminal material is added within the holes formed by the laser-ablation. The dielectric is again ablated to reduce the height of the substrate and further expose the terminals to form the final semiconductor package. The terminal material may be solder so that curved “solder ball” hemispherical surfaces are provided on an exposed surface of the semiconductor package. Alternatively, in concert the terminal may be internal terminals or posts for connecting a semiconductor die to the substrate within the semiconductor package.

### CROSS-REFERENCE TO RELATED APPLICATIONS

The present application is a continuation-in-part of U.S. patent application entitled “INTEGRATED CIRCUIT SUBSTRATE HAVING LASER-EXPOSED TERMINALS”, Ser. No. 10/603,878 filed Jun. 24, 2003, having at least one common inventor and assigned to the same assignee and which is a continuation-in-part of U.S. patent application Ser. No. 10/138,225 filed May 1, 2002. The specifications of the above-referenced patent applications are herein incorporated by reference.

### FIELD OF THE INVENTION

The present invention relates generally to semiconductor packaging, and more specifically, to a substrate having laser embedded terminals for providing external and/or internal electrical terminals of a semiconductor package.

### BACKGROUND OF THE INVENTION

Semiconductors and other electronic and opto-electronic assemblies are fabricated in groups on a wafer. Known as “dies”, the individual devices are cut from the wafer and are then bonded to a carrier. The dies must be mechanically mounted and electrically connected to a circuit.

The mechanical mounting and electrical connecting of semiconductor dies is typically provided in a semiconductor package that encapsulates one or more die for protection and includes electrical contacts on one or more external surfaces of the encapsulation. The electrical contacts often provide the mechanical mounting feature(s) as well, but in some semiconductor packages, the mechanical mounting is supplemented or provided entirely by a separate mechanism such as an external mounting clip or socket.

With increasing levels of integration due to semiconductor process size shrink, as well as the fabrication of larger dies and/or inclusion of multiple dies within a package, an increasing number of terminals are frequently required for interfacing a semiconductor package to external circuits. However, the placement of such external terminals must provide sufficient spacing such that the semiconductor package fabrication or attachment process does not cause faults such as shorts between the electrical terminals. Therefore, there is a generally a lower limit on the spacing density of the terminals and a limited number of terminals that can be provided on a side of a semiconductor package without increasing its size.

Further, it is usually not desirable to increase the size of a semiconductor package to add terminals, not only from a cost, weight and volume standpoint, but because the increased distance between terminals represents additional circuit length, which can increase electromagnetic interference, propagation delay and terminal capacitance that functionally affect the operation of the electronic systems in which the semiconductor package is used.

Once the semiconductor package substrate has been fabricated, and often after the entire semiconductor packaging process is complete, external terminals such as solder balls are added to the package to provide the electrical and mechanical interface. One way in which the solder balls are prevented from shorting, both during the terminal attachment process and during later mounting of the semiconductor package, is by the use of a soldermask layer that provides some isolation between lands to which the solder balls are mounted. The soldermask prevents “wicking” between adjacent lands during solder ball attach and re-flow, but adds cost and time to the manufacturing process.

Internal terminal connections between the semiconductor dies and the substrate are also increasing in density and in the case of solder ball/solder bump attachments also have limitations on the inter-terminal spacing in order to provide sufficient distance between terminals in order to prevent wicking and shorting.

Therefore, it would be desirable to provide packaging methods and semiconductor packages having improved interconnect density with a low associated manufacturing cost. It would be further desirable to provide such a semiconductor package that does not require a soldermask. It would further be desirable to provide a solder ball/bump attach method and structure that provide for reduced inter-terminal spacing in general.

### SUMMARY OF THE INVENTION

The above objectives of providing improved interconnect density, a low associated manufacturing cost, eliminating the need for a soldermask layer and reducing inter-terminal spacing in general are provided in a semiconductor package, are achieved in a substrate for a semiconductor package and a method for manufacturing a semiconductor package.

A dielectric substrate layer is fabricated with internal terminal lands and laser-ablation is used to remove the dielectric above the terminal lands. The terminal material is then added in the holes formed by the laser-ablation, providing a semiconductor package having partially embedded terminals.

Finally, the surface of the dielectric surrounding the terminals is again laser-ablated to further expose the terminals and reduce the height of the dielectric.

The terminals may be external terminals for interfacing the semiconductor package to an external circuit and/or internal terminals for attaching, for example, a “flip-chip” die to the substrate.

### BRIEF DESCRIPTION OF THE DRAWINGS

FIGS. 1A-1E are pictorial diagrams depicting a cross-sectional view of stages of preparation of a semiconductor package substrate in accordance with an embodiment of the present invention;

FIG. 2 is a pictorial diagram depicting a cross-sectional view of a semiconductor package in accordance with an embodiment of the present invention;

FIGS. 3A-3B are a pictorial diagram depicting a cross-sectional view of other stages in the preparation of a semiconductor package substrate in accordance with another embodiment of the present invention;

FIG. 4A is a pictorial diagram depicting a cross-sectional view of a semiconductor package in accordance with another embodiment of the present invention; and

FIG. 4B is a pictorial diagram depicting a cross-sectional view of a semiconductor package in accordance with still another embodiment of the present invention.

The invention, as well as a preferred mode of use and advantages thereof, will best be understood by reference to the following detailed description of illustrative embodiments when read in conjunction with the accompanying drawings, wherein like reference numerals indicate like parts throughout.

### DETAILED DESCRIPTION

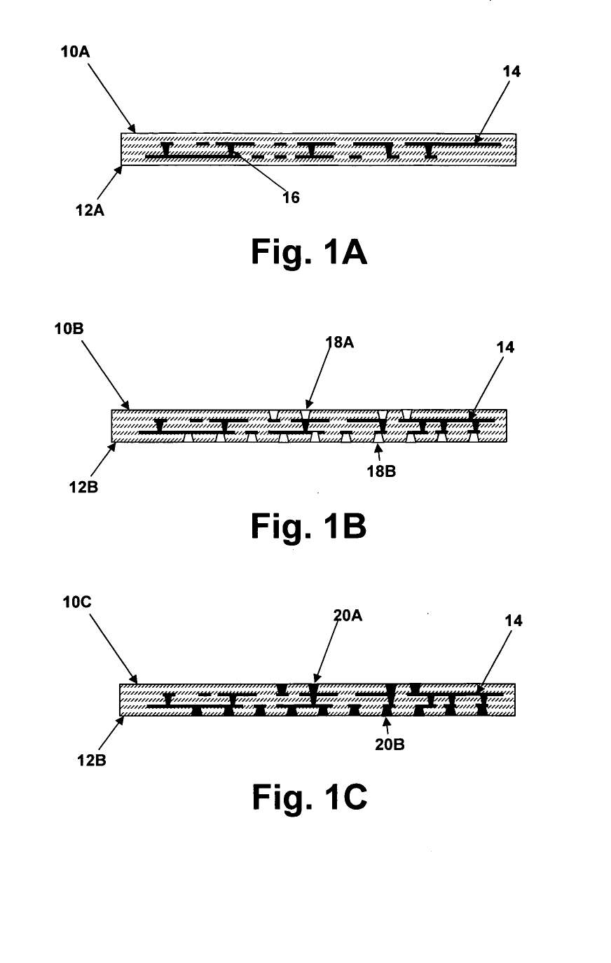

Referring now to the figures and in particular to FIGS. 1A through 1E, cross-sectional views of stages of preparation of a substrate in accordance with an embodiment of the present invention are shown. A first substrate stage 10A, includes a dielectric layer 12A that has an embedded circuit pattern 14 that may include multiple circuit layers as shown. The above-incorporated parent U.S. patent application, as well as the applications from which it depends disclose the fabrication and structure of laser-embedded circuit patterns, laminated circuit patterns and the like. The present invention applies to buried circuit patterns such as circuit pattern 14 and a method and structure that provide low profile, high density solder bumps for providing external terminals of the semiconductor package and/or for attachment of flip-chip dies within the semiconductor package.

Substrate stage 10A may be fabricated from a dielectric film tape such as a polyimide film. Alternatively, substrate stage 10A may be fabricated from a rigid or semi-rigid dielectric material such as polyimide resin having, in accordance with another embodiment of the present invention. Rigid substrate layers may be cured epoxy resin, FR4, or other substrate materials commonly used to form integrated circuit substrates.

Substrate stage 10A is laser-ablated from one or both side to expose terminal areas provided in circuit pattern 14 through holes 18A and/or 18B as shown in FIG. 1B, providing ablated substrate stage 10B. An excimer laser is preferably used to ablate dielectric layer 12A in order to provide sharp features, but other high power laser types can be used as well, as long as dielectric material can be removed to form holes 18A and/or 18B.

Next, as shown in FIG. 1C, solder is paste-screened into holes 18A and 18B to fill holes 18A and 18B with a first volume of solder. Other conductive material may be used and may be preferable in certain applications as will be described in further detail below. Holes 18A and 18B are generally overfilled by the paste screening process and then the surface(s) of dielectric layer 12B (and the applied solder) are planarized by machining/polishing the surfaces to provide a substrate stage 10C with filled holes 20A and 20B.

Then, as shown in FIG. 1D, one type of substrate structure 10D that can be produced from the substrate stage 10C of FIG. 1C is shown. Solder is re-flowed onto both sides of substrate stage 10C to yield solder bumps 22A and 22B on both sides of substrate 10D. Solder bumps 22A and 22B extend slightly beyond the surface of dielectric layer 12B to provide a hemispherical shape at the terminal ends. Finally as shown in FIG. 1E, dielectric layer 12B is again laser-ablated to reduce the substrate thickness and expose more of solder bumps 22A and 22B below dielectric layer 12C, so that they can be properly used in re-flow/attach operations. Resulting substrate 10E has solder bumps 22C and 22D with a shaped profile that tapers toward the terminal areas of circuit pattern 14 where solder bump 22C and 22D terminals are connected.

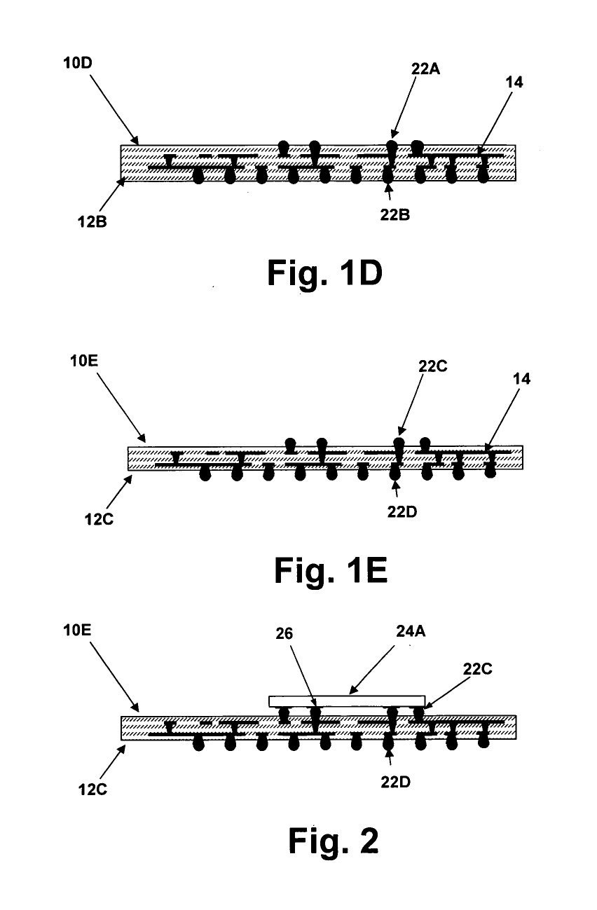

FIG. 2 shows an integrated circuit package prior to any encapsulation that includes a semiconductor die 24A mounted to bumps 22C. Bumps 22D are used to provide a ball grid array (BGA) terminal pattern for mounting to an external circuit. One unique feature of the above described process is that holes and bumps of variable diameter can be produced across the surface of the substrate and that the terminals can vary from cylindrical posts to shaped or conically tapered cross-sections as shown. For example, power terminals can be made very large and signal terminals can be made smaller. Another feature of the present invention is that different metals or conductor compositions can be selectively applied within the holes 18A, 18B and/or to filled holes 20A, 20B. For example, a thermal conductive pattern for a heat conductor (which may or may not provide an electrical conductor) could be filled with copper or aluminum rather than solder and bonded to an external heatsink arrangement. Another use of alternative material is illustrated below.

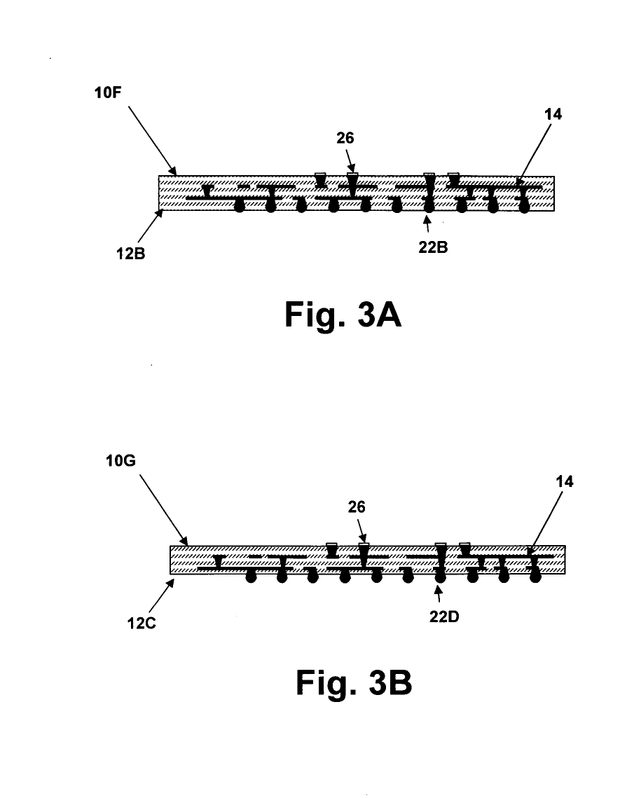

Referring now to FIG. 3A, another substrate stage 10F that can be produced from the substrate state 10C of FIG. 1C is shown. In the depicted embodiment, a plating 26 is applied to the top side of substrate 10D instead of re-flowing solder bumps. Subsequent to plating, as shown in FIG. 3B (or alternatively prior to plating), dielectric layer 12B is laser-ablated to expose more solder balls 22B to yield solder ball terminals 22D of final substrate assembly 10G below dielectric layer 12C.

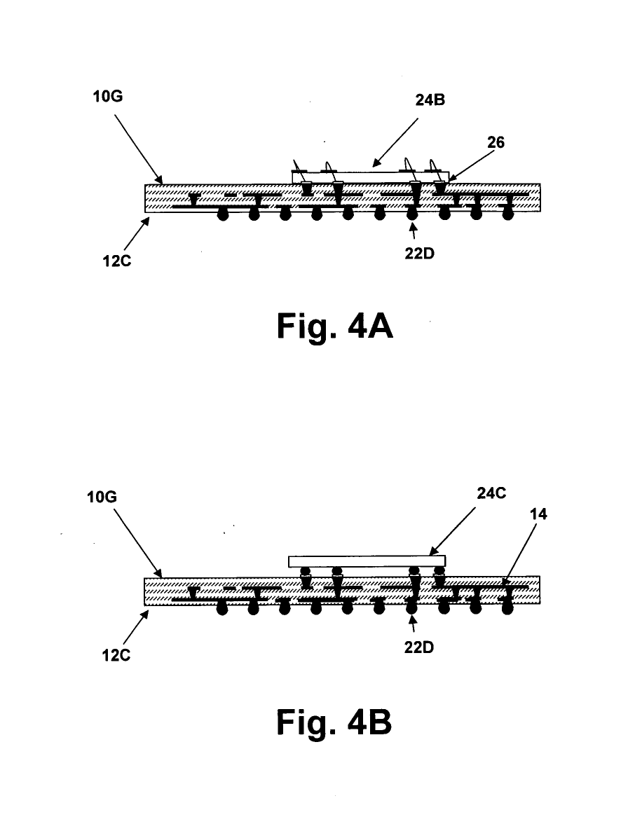

Generally, the material applied within top holes 18A will be a conductive paste such as copper rather than solder, so that OSP or other plating materials may be applied to the tops of filled holes 20A. Plating 26 is provided for wire-bonding electrical connections of a semiconductor die 24B as shown in FIG. 4A to form a semiconductor package as shown.

An alternative flip-chip mounting is also possible with the substrate of FIG. 3B, as illustrated in FIG. 4B. A flip-chip die 24C that already includes solder terminal can be mounted to substrate 10G with or without plating 26. In the flip-chip mounting configurations of the present invention, it should be understood that the solder bumps may be included on semiconductor die 24C, substrate 10G or both.

The above description of embodiments of the invention is intended to be illustrative and not limiting. Other embodiments of this invention will be obvious to those skilled in the art in view of the above disclosure and fall within the scope of the present invention.

1. A substrate for a semiconductor package, comprising:
at least one dielectric layer;
a circuit material layer embedded within the dielectric layer and having terminal areas with primary dimensions extending over an area parallel to an external surface of the dielectric layer and located within the dielectric layer, and wherein the dielectric layer defines holes formed between the terminal areas and the external surface of the dielectric layer; and
conductive terminal material deposited within the holes and extending beyond the external surface of the dielectric layer outside of the holes, whereby the terminal material provides electrical connections between the terminal areas and one or more electrical devices, wherein the holes include holes of at least two substantially differing diameters, whereby a cross-sectional amount of the terminal material can be adapted for each electrical connection.

2. The substrate of claim 1, wherein the holes are laser-ablated holes.

3. The substrate of claim 1, wherein the holes have a tapering profile in a direction perpendicular to the external surface of the dielectric layer with a smaller diameter at the terminal areas and a larger diameter at the external surface of the dielectric layer.

4. The substrate of claim 1, wherein the terminal material is solder.

5. The substrate of claim 1, wherein the terminal material forms a substantially hemispherical bump beyond the external surface of the dielectric layer, whereby the electrical connections can be made by ordinary solder bump attachment methods after fabrication of the substrate.

6. The substrate of claim 5, wherein the external surface of the dielectric layer is a peripheral surface of the semiconductor package, and wherein the electrical connections are solder bump terminals disposed on the peripheral surface for attachment of the semiconductor package to an external circuit.

7. The substrate of claim 5, wherein the external surface of the dielectric layer is an internal surface of the semiconductor package for attaching a semiconductor die, and wherein the electrical connections are solder bump terminals disposed on the internal surface for connection of electrical terminals of the semiconductor die to circuit patterns within the substrate.

8. The substrate of claim 1, wherein the external surface of the dielectric layer is a peripheral surface of the semiconductor package, and wherein the electrical connections are interconnect terminals disposed on the peripheral surface for attachment of the semiconductor package to an external circuit.

9. (canceled)

10. The substrate of claim 1, wherein the terminal material includes at least two differing materials, wherein each one of the holes is filled with one of the at least two differing materials, whereby the terminal material can be selected for each electrical connection.

11. The substrate of claim 1, wherein the terminal material at each electrical connection includes at least two volumes of the terminal material, a first volume extending from the terminal areas to the external surface and having a first crystalline characteristic and a second volume extending from the external surface to beyond the external surface and having a second crystalline characteristic.

12. The substrate of claim 11, wherein the terminal material is solder, wherein the first volume is filled with paste screened solder having a machined face at the external surface and wherein the second volume comprises re-flowed solder bumps attached to the first volume.

13. A semiconductor package, comprising:
a semiconductor die;
a substrate comprising at least one dielectric layer and a circuit material layer embedded within the dielectric layer and having terminal areas with primary dimensions extending over an area parallel to an external surface of the dielectric layer and located within the dielectric layer, and wherein the dielectric layer defines holes formed between the terminal areas and the external surface of the dielectric layer; and
a plurality of electrical terminals formed from conductive terminal material deposited within the holes and extending beyond the external surface of the dielectric layer outside of the holes, whereby the terminal material provides electrical connections between the terminal areas and the semiconductor die, wherein the holes include holes of at least two substantially differing diameters, whereby a cross-sectional amount of the terminal material can be adapted for each electrical connection.

14. The semiconductor package of claim 13, wherein the holes are laser-ablated holes having a tapering profile in a direction perpendicular to the external surface of the dielectric layer with a smaller diameter at the terminal areas and a larger diameter at the external surface of the dielectric layer.

15. The semiconductor package of claim 13, wherein the external surface of the dielectric layer is a peripheral surface of the semiconductor package, and wherein the electrical terminals are solder bump terminals disposed on the peripheral surface for attachment of the semiconductor package to an external circuit.

16. The semiconductor package of claim 13, wherein the external surface of the dielectric layer is an internal surface of the semiconductor package for attaching the semiconductor die, and wherein the electrical terminals are solder bump terminals disposed on the internal surface for connection of electrical terminals of the semiconductor die to circuit patterns within the substrate.

17-20. (canceled)

21. A substrate for a semiconductor package, comprising:
at least one dielectric layer having an internal surface and a peripheral surface;
a circuit material layer embedded within the dielectric layer and having terminal areas located within the dielectric layer, and wherein the dielectric layer defines upper holes between the terminal areas and the internal surface of the dielectric layer and lower holes between the terminal areas and the peripheral surface of the dielectric layer;
a conductive first terminal material within the upper holes for forming electrical connections between the terminal areas and one or more electrical devices; and
a conductive second terminal material deposited within the lower holes and extending beyond the peripheral surface of the dielectric layer for attachment of the semiconductor package to an external circuit, wherein the upper and lower holes include holes of at least two substantially differing diameters.

22. The substrate of claim 21 wherein the first terminal material comprises copper and wherein the second terminal material comprises solder.

23. The substrate of claim 22 further comprising a plating material on the first terminal material, the plating material for forming wire-bonding electrical connections with the one or more electrical devices.

24. (canceled)

25. The substrate of claim 1 wherein the terminal material forms power terminals and signal terminals, the power terminals being larger than the signal terminals.

26. The substrate of claim 21 wherein the first terminal material forms power terminals and signal terminals, the power terminals being larger than the signal terminals.
